(19) United States
(12) Patent Application Publication
(10) Pub. No.: US 2025/0169045 A1
(43) Pub. Date: May 22, 2025

(54) EXCHANGEABLE ELECTRONICS ASSEMBLY OF A MOTOR VEHICLE

(71) Applicant: Robert Bosch GmbH, Stuttgart (DE)

(72) Inventors: Florian BURGER, Wendlingen (DE); Markus WIEDEMANN, Soergenloch (DE); Robert KORNHAAS, Spraitbach (DE)

(21) Appl. No.: 18/832,620

(22) PCT Filed: Jan. 31, 2023
(86) PCT No.: PCT/EP2023/052260

§ 371 Date: Jul. 24, 2024

(30) Foreign Application Priority Data
Feb. 28, 2022 (DE) 10 2022 202 018.9

(51) Int. Cl. H05K 7/20; B60R 16/03; H05K 7/14

(52) U.S. Cl. CPC H05K 7/20872; B60R 16/03; H05K 7/1452

(57) ABSTRACT

An exchangeable electronics assembly of a motor vehicle. The assembly includes at least one circuit board with at least one electronics component to be cooled arranged on the circuit board, at least one plug oriented in parallel to an insertion direction of the electronics assembly into a housing accommodating a plurality of electronics assemblies, at least one housing connected to the circuit board and at least partially surrounding the circuit board, at least one insertion mechanism that cooperates with at least one receptacle of the housing accommodating a plurality of electronics assemblies, and at least one heat-conducting element in thermal contact with the electronics component, wherein the heat-conducting element includes a contact surface oriented transverse to the insertion direction for thermally linking a cooler, wherein the plug protrudes further than the contact surface in the insertion direction.

### FIELD

The present invention relates to an exchangeable electronics assembly of a motor vehicle.

### BACKGROUND INFORMATION

Systems and methods for passive cooling of components within electrical devices are described in European Patent Application EP 2961252 A1. An electrical unit comprises a backplane assembly having openings and a heat sink arranged along the rear end of the cabinet parallel to the backplane assembly.

### SUMMARY

An object of the present invention is to provide an improved thermal link, in particular in the insertion direction. This problem may be solved by features of the present.

By means of the electronics assembly according to features of the present invention, the heat transfer between the exchangeable electronics assembly and the housing can take place not laterally, but in the insertion direction. This achieves a relatively low thermal resistance because the direction of the thermal contact coincides with the direction of the electrical contact toward the mechanical fastening. In addition, by inserting the electronics assembly, both the electrical contact to the rear circuit board and the thermal contact to the cooler can be realized at the same time. For example, sufficient thermal contact is achieved through appropriate surface pressure. This is achieved by a corresponding design of the electronics assembly.

In an expedient further development of the present invention, the contact surface is designed such that it serves to link a cooler that is arranged in front of the circuit board as seen in the insertion direction. This arrangement allows the heat transfer to be further improved because a larger contact surface is now possible. Thanks to the relative proximity of the cooler to the heat-generating electronics component, the heat-conducting element can be made relatively compact.

In an expedient further development of the present invention, the plug and contact surface are located on opposite sides. This allows cooling to be achieved via the front side of the housing, into which preferably a plurality of electronics assemblies can be inserted. This simplifies the linking of the cooling system.

In an expedient further development of the present invention, the plug is designed to contact the rear circuit board by protruding through at least one opening of the cooler. This allows easy contact between the electronics assembly and the circuit board located at the rear.

In an expedient further development of the present invention, the heat-conducting element has at least one surface oriented in parallel to the insertion direction for absorbing the waste heat generated by the electronics component, and at least one portion having a 90° bend for linking to the contact surface oriented transverse to the insertion direction. This allows the contact surface between the electronics assembly and the cooler to be increased.

In an expedient further development of the present invention, a further circuit board is provided, wherein the housing is connected to both circuit boards and/or the plug is arranged on the one circuit board and the electronics component to be cooled is arranged on the other circuit board and/or the two circuit boards are connected to one another via a contact. The arrangement is suitable in particular for more complex electronics assemblies having a plurality of circuit boards, which are becoming increasingly common in vehicles with high-performance computers. For a later retrofit with more powerful components, for example, only one circuit board could be replaced.

In an expedient further development of the present invention, the housing comprises at least one arm, preferably four arms, that protrude over the further circuit board and/or the housing can be connected to the circuit board and/or the housing is designed to mechanically hold the further circuit board and/or is designed to hold the heat-conducting element and/or is designed to be attached to a carrier. Depending on the application, the housing can flexibly realize in particular the mechanical force absorption in the insertion direction and optionally also the thermal linking of other electronics components to the contact surface.

In an expedient further development of the present invention, at least one further housing is provided, which is connected to a further circuit board and a further heat-conducting element and to the carrier. This allows for a simple, in particular symmetrical, construction of an electronics assembly having a plurality of circuit boards to be easily assembled from a manufacturing perspective.

In an expedient further development of the present invention, the electronics assembly comprises at least one, in particular frame-shaped, carrier for accommodating at least one circuit board and/or for accommodating at least a part of a housing and/or for mechanical contact with receptacles arranged in the housing surrounding the electronics assemblies. This carrier allows the housing halves to be connected to each other. The carrier can also be used as an insertion mechanism. The stability of the arrangement, in particular in the insertion direction, is further increased.

In an expedient further development of the present invention, at least one further heat-conducting element, in particular a flexible heat-conducting material, is provided between the heat-conducting element and the cooler and/or the electronics component. This improves the thermal linking.

In an expedient further development of the present invention, the heat-conducting element comprises at least one heat-conducting plate and/or at least one cavity filled with a heat-conducting material. This can further improve heat dissipation. In an expedient further development of the present invention, the housing has at least one recess for the heat-conducting element and/or at least one contact surface, in particular projecting inward, for thermally cooling at least one electronics component. The housing can thus perform both holding functions for the heat-conducting element and heat dissipation itself.

In an expedient further development of the present invention, a pressing means, in particular at least one screw or lever, is provided in order to reduce the relative distance between the heat-conducting element or the contact surface and the cooler. This further improves heat transfer. At the same time, a secure contact of the plug can also be achieved.

The electronics assembly is preferably part of an overall system that consists of a plurality of electronics assemblies arranged in a housing.

Further expedient developments of the present invention can be found in the disclosure herein.

### BRIEF DESCRIPTION OF THE DRAWINGS

FIG. 1 is a perspective overall view of an exemplary embodiment of an apparatus having a plurality of exchangeable electronics assemblies in an exploded representation, according to the present invention.

FIG. 2 is a side view of an exchangeable electronics assembly, according to an example embodiment of the present invention.

FIG. 3 is a perspective view of the exchangeable electronics assembly of the present invention from behind.

FIG. 4 is a side view of a plurality of exchangeable electronics assemblies, together with a cooler, rear circuit boards and carrier plate in an assembled state, according to an example embodiment of the present invention.

FIG. 5 is a side view of an alternative exemplary embodiment of an exchangeable electronics assembly, according to the present invention.

FIG. 6 is a side view of a further alternative exemplary embodiment of an exchangeable electronics assembly, according to the present invention.

FIG. 7 is a perspective view of the exemplary embodiment according to FIG. 6, according to the present invention.

FIG. 8 is a perspective view of a housing of the exemplary embodiment of the present invention according to FIGS. 6 and 7.

FIG. 9 is a cross section of a further alternative exemplary embodiment in a front view, according to the present invention.

FIG. 10 is a cross section of the further alternative exemplary embodiment of the present invention according to FIG. 9 in a side view.

FIG. 11 is a side view of a further alternative exemplary embodiment, according to the present invention.

FIG. 12 is a side view of a plurality of exchangeable electronics assemblies according to FIG. 5 together with a cooler integrated into the maintenance flap, according to the present invention.

FIG. 13 is a side view of a plurality of exchangeable electronics assemblies for air cooling, according to an example embodiment of the present invention.

### DETAILED DESCRIPTION OF EXAMPLE EMBODIMENTS

The present invention is illustrated schematically on the basis of a plurality of exemplary embodiments and will be described in detail below with reference to the drawings.

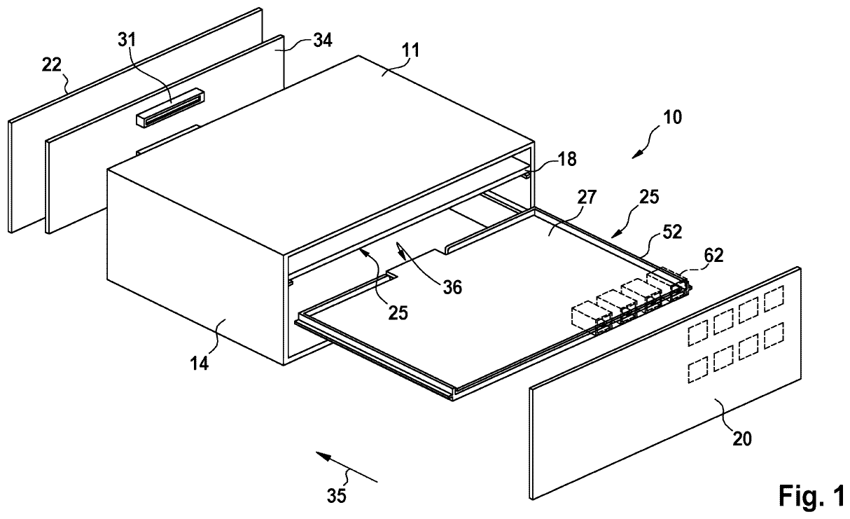

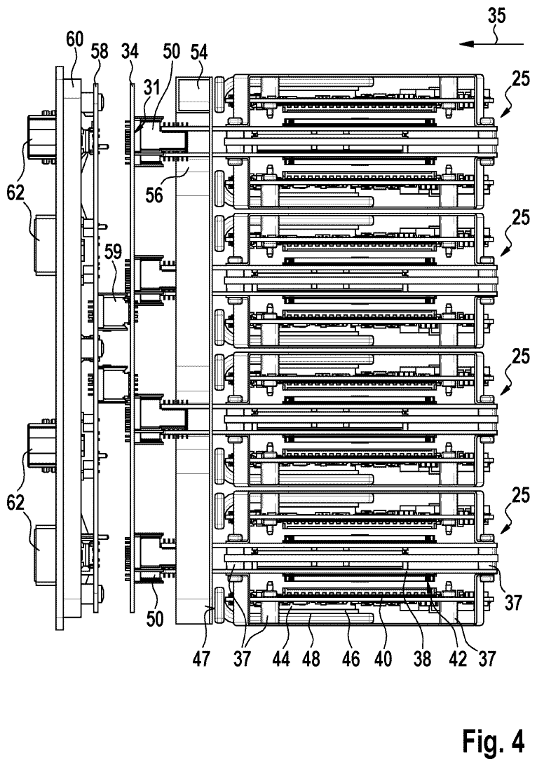

In FIG. 1, the apparatus 10 comprises at least two electronics assemblies 25 and a housing 11 that at least partially surrounds them. Depending on the application, however, further electronics assemblies 25 can be exchangeably arranged in the housing 11. The housing 11 has two side surfaces 14. The housing 11 is closed at the rear via a rear-side housing cover 22, in particular by a mechanical fixing such as a screw connection. At least one circuit board 34 is arranged in parallel to the rear-side housing cover 22 and perpendicular to the exchangeable electronics assemblies 25 or an insertion direction 35 of the electronics assemblies 25. Plug-in connections 31 are provided on the circuit board 34, which plug-in connections establish electronic contact between the individual electronics assemblies 25 and the circuit board 34. By way of example, further electronics components (not specifically shown) are provided on the circuit board 34, which components, for example, control the communication processes. Plugs 62 for external contact can be placed on the circuit board 34. More precise details of the components arranged on the rear side of the apparatus 10 can be found in particular in FIG. 4. Optionally, plugs 62 can be attached to the front side of the circuit board 38, which plugs then protrude through corresponding openings (also indicated by dashed lines) in the front side 20.

The front side 20 provides access to the exchangeable electronics assemblies 25 arranged inside the apparatus 10. The front side 20 can be opened and closed using mechanical fixings. On the inside of the side surfaces 14 of the housing 11, a plurality of receptacles 18 are provided as an example of a possible insertion mechanism. These substantially rail-shaped receptacles 18 are used for reversibly accommodating, inserting and/or clamping the exchangeable electronics assemblies 25 in the insertion direction 35. The electronics assembly 25 can, for example, comprise one or more circuit boards 38, 40 or an electronics unit. The electronics units having associated electronics components 44 (shown later) comprise in particular high-performance computer cores that perform particularly computationally intensive functions in the motor vehicle. These functions can include, for example, autonomous or semi-autonomous driving functions, infotainment, communication interfaces between different bus systems (Ethernet, CAN, LIN, etc.) or gateway functionalities, certain security applications for granting authorization, for example to access the motor vehicle from outside, or other operations in the motor vehicle that require particularly high computing power. The electronics components 44 are particularly preferably powerful processors, multi-core processors or highly integrated circuits (SoC, system-on-chip), which are characterized by high power dissipation.

The circuit board 38, 40 of the electronics assembly 25 is at least partially enclosed on at least one side by a housing 52 or a housing half 52. In the side regions, the housing half 52 extends into corresponding projections that can be placed on the receptacles 18 in the housing 11 or inserted into the receptacles 18. In this exemplary embodiment, the housing half 52 almost completely encloses the circuit board 38, 40 on the sides.

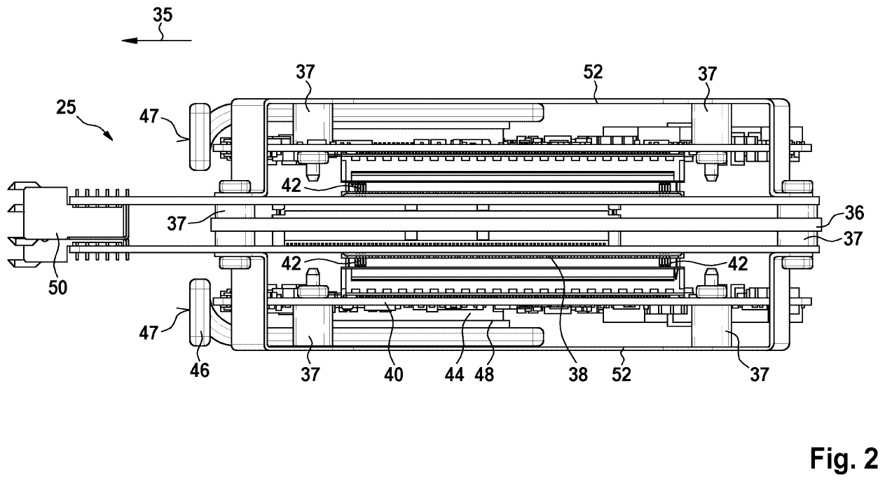

The exemplary embodiment according to FIG. 2 shows an example of an exchangeable electronics assembly 25. A circuit board 38 is fastened to a stable carrier 36. This is done, for example, by means of fastening means 37, which can be designed as screw connections with spacer sleeves. The circuit board 38 could, for example, comprise the main board. In the exemplary embodiment, a further circuit board 40 is also arranged in parallel to the circuit board 38. Depending on the exemplary embodiment, however, only a single circuit board 38 could be provided. Electronics components 44 are also arranged on the further circuit board 40, for example designed as what is known as a daughter board. Such electronics components 44, which are characterized by high heat development, are arranged on the further circuit board 40 in the exemplary embodiment. To dissipate the waste heat of these electronics components 44, a link 48 is used to link them to a heat-conducting element 46 in a heat-conducting manner. This thermal link 48 is designed, for example, as what is known as a gap pad, a flexible heat-conducting material. Electronics components 44 that cannot be placed on the further circuit board 40 but are nevertheless to be thermally linked to a cooler 54 must be arranged in the region of the bent heat-conducting element 46 and must also be thermally contacted therewith. Alternatively, the electronics components 44 can also be linked to the heat-conducting element 46 via the housing 52, which is made, for example, of a heat-conducting material such as aluminum, and/or via further heat-conducting elements such as heat pipes (tubular heat-conducting arrangements optionally filled with a heat-conducting medium).

The heat-conducting element 46 is oriented on one side substantially in parallel to the surface of the further circuit board 40. At the other end, it protrudes over the end of the further circuit board 40. The heat-conducting element 46 has a contact surface 47 to the cooler 54 in this region. The contact surface 47 is oriented substantially transverse to the circuit board 38, 40 or transverse to the insertion direction 35 of the electronics assembly 25. The contact surface 47 is preferably designed as a flat plane. The normal vector of this plane is parallel to the insertion direction 35. To improve heat transfer, the contact surface 47 can extend at least almost over the entire width of the further circuit board 40. The heat-conducting element 46 could, for example, be designed as a vapor chamber or heat pipe 45, a hollow body or tube filled with a heat-conducting medium. Alternatively, the heat-conducting element 46 consists only of a particularly heat-conducting material such as copper or the like and could, for example, be designed in the form of a plate as a solid part without a cavity. The heat-conducting element 46 could be designed as an insert.

Furthermore, at least one housing half 52 is provided which at least partially encloses the circuit boards 38, 40 and the heat-conducting element 46. In the housing half 52, in particular four arms protrude outward over the outer sides of the further circuit board 40. The arms of the housing half 52 extend in an L-shape and can thus rest on the circuit board 38 at its corners and be connected, for example screwed, to the carrier 37 via the fastening means 37. To exchange the circuit boards 38, 40 later, the fastening elements 37 can simply be released again. A contact 42 is provided between the two circuit boards 38, 40 in order to electrically link the further circuit board 40 to the circuit board 38. At least one plug 50 is arranged on the end face of the circuit board 38. The electrical link of the electronics assembly 25 is made via said plug 50 and the rear-side circuit board 34 when the electronics assembly 25 is inserted into the housing 11.

The exemplary embodiment according to FIG. 2 is symmetrical (with the carrier 36 as the axis of symmetry). Thus, even four circuit boards 38, 40 can be accommodated in the exchangeable electronics assembly 25. In this case, two housing halves 52 are provided, each of which connects two circuit boards 38, 40 to the carrier 36 to form a structural unit. A further plug 50 serves to electrically link the second half to the further circuit boards 38, 40.

The carrier 36 preferably projects, in the insertion direction 35, slightly laterally relative to the parallel outer sides of the circuit boards 38, so that the carrier 36 can be inserted into the receptacles 18 or the insertion mechanism on the housing 11.

What this and all other exemplary embodiments have in common is that the plug 50 protrudes further in the insertion direction 35 than the contact surface 47.

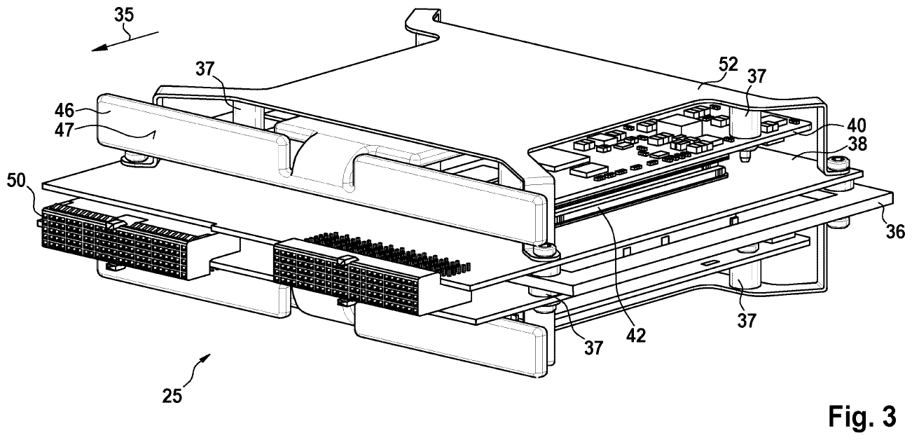

FIG. 3 is a perspective view of the exchangeable electronics assembly 25. It can be seen that the contact surface 47 of the heat-conducting element 46 extends substantially over the entire width of the circuit board 38. The contact surface 47 is substantially rectangular. In an in particular central region of the heat-conducting element 46, the contact surface 47 oriented transverse to the insertion direction 35 is connected to a portion of the heat-conducting element 46 oriented in parallel to the circuit board 38, 40. This portion of the heat-conducting element 46 oriented in parallel to the circuit board 38, 40 is connected in a heat-conducting manner to the electronics component(s), for example via a thermal link 48. A portion of the circuit board 38 projects beyond the contact surface 47 in the insertion direction 35 and is provided with the plugs 50 at the end.

In the exemplary embodiment according to FIG. 4, a vertical cooler 54 is arranged between a plurality of, in particular at least two, exchangeable electronics units 25 and at least one rear-side circuit board 34 oriented transverse to the circuit boards 38, 40. When the electronics assemblies 25 are inserted, their plug 50 passes through an opening 56 in the cooler 54 into the region of the rear circuit board 34 and contacts a corresponding mating plug there. At the same time, a further heat-conducting element 49, in particular a gap pad (a flexible heat-conducting material that thermally bridges a gap between the heat-conducting element 46 and the cooler 54), is compressed between the heat-conducting element 46 and the cooler 54. For example, a loosely guided screw is used to fix the exchangeable electronics assemblies 25. Said screw engages with a thread in the cooler 54 and is tightened from the front side 20 (maintenance flap) after the electronics assemblies 25 have been inserted. The screw can be used to apply the force required for the final insertion of the plugs 50 and the compression of the further heat-conducting element 49. Alternatively, two levers on the sides of the electronics assemblies 25 could apply this force.

The cooler 54 is oriented transverse to the insertion direction 35 of the electronics assemblies 25. The openings 56 in the cooler 54 are dimensioned in the insertion direction 35 so that the respective plugs 50 can be pushed through them. The cooler 54 could, for example, be provided with cooling circuits through which a heat medium such as water flows. Appropriate connections on the cooler 54 for a coolant circuit must be provided. Redundant cooling could be realized by the cooler 54 containing at least two independent water circuits to which at least two independent cooling circuits are connected. Alternatively, the cooler 54 could also be provided with cooling fins to dissipate the heat into an airflow. Preferably, the cooler 54 is arranged in front of the rear circuit board 34. However, this could also be in the region of the front side of the apparatus 10. The cooler 54 cools at least two, preferably a plurality of, exchangeable electronics assemblies 25. By arranging the cooler 54 transverse to the insertion direction 35 and also correspondingly aligning the contact surface 47 of the heat-conducting element 46 transverse to the insertion direction 35, a high thermal contact can be achieved when inserting the electronics assemblies 25, for example by means of surface pressure.

In the exemplary embodiment according to FIG. 4, the housing 11 is closed by a rear-side housing cover 22 designed as a carrier 60 or carrier plate for plugs 62. Contacting of the apparatus 10 or the exchangeable electronics assemblies 25 located therein is carried out from the outside via these plugs 62, by the plugs 62 being connected in an electrically conductive manner to a further rear circuit board 58 (backplane) oriented transverse to the insertion direction 35. Said further rear circuit board 58 is connected on the rear side via further connections to the rear circuit board 34 arranged parallel to said further rear circuit board, while the plugs 50 of the electronics assemblies 25 are accommodated on the mating plugs of the further rear circuit board oriented toward the exchangeable electronics assemblies 25. Alternatively, however, only a single rear circuit board 34 could be provided, as indicated in FIG. 1.

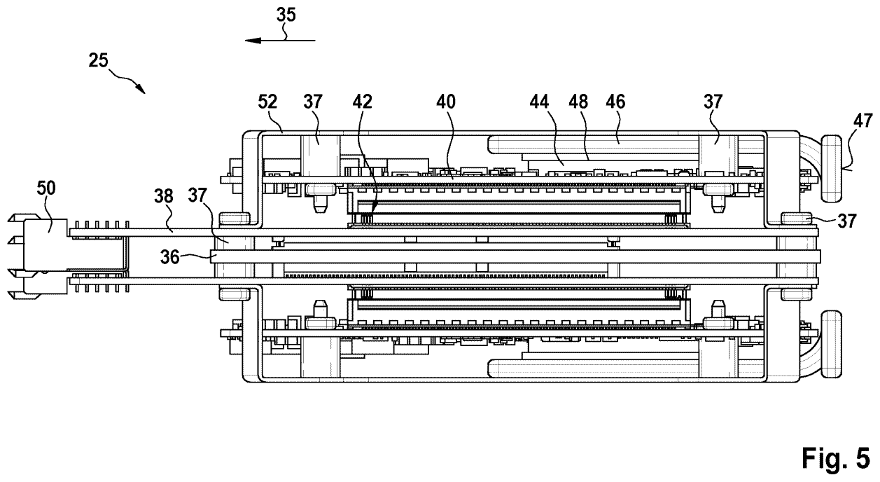

Alternatively, the cooling function can also be integrated into the front side (maintenance flap) to be opened. This is shown by way of example in FIGS. 5 and 11-13. In this case, the heat-conducting element 46 is installed on the electronics assembly 25 rotated by 180°. Thus, the contact surface 47 is now arranged on the side of the circuit board 38, 40 opposite the plug 50. The contact surface 47 now projects forward beyond the circuit boards 38, 40 in order to come into thermal contact with the front side 20 designed as a cooler 54. The thermal contact is made by closing the front side 20 and the associated compression of the further heat-conducting element 49, which is arranged between the outside of the contact surface 47 and the inside of the cooler 54. Otherwise, the structure remains the same as described in connection with FIGS. 2 and 3. In particular, the contact surface 47 is again oriented transverse to the insertion direction 35. Likewise, the surface of the cooler 54 for thermally linking with the heat-conducting element 46 is accordingly designed transverse to the insertion direction 35 or parallel to the rear circuit board 34 and is arranged in front of the rear circuit board 34, but also in front of the exchangeable electronics assemblies 25.

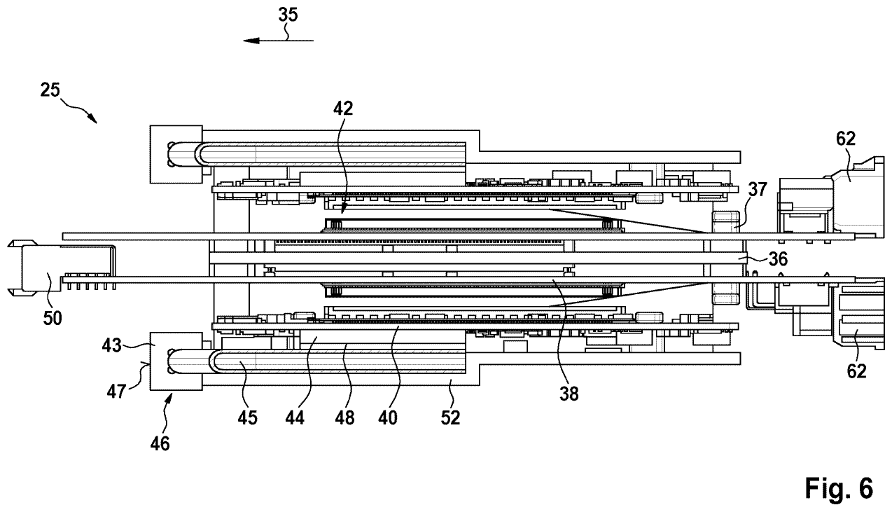

FIG. 6 is a cross section of a further exemplary embodiment of the electronics assembly 25. On the one hand, the exemplary embodiment differs from the above-described ones in that at least one external plug 62 is arranged on the front side (relative to the insertion direction 35) of the electronics assembly 25. In the exemplary embodiment, the plug 62 is arranged on the circuit board 38. The contact direction of the plug 62 is parallel to the insertion direction 35. Depending on the application, additional plugs 62 can be arranged on the circuit board 38. The plugs 62 protrude beyond the front edge of the circuit board 38. Accordingly, corresponding recesses are provided in the front side 20 to be opened, through which recesses these plugs 62 protrude. Nevertheless, at least one plug 50 is provided at the end of the electronics assembly 25 for contacting the transverse rear-side circuit board 34. As in the above-described exemplary embodiments, the plug 50 is arranged at the end of the slightly protruding circuit board 38.

The exemplary embodiment according to FIG. 6 again comprises the carrier 36, on which the circuit board 38 and a further circuit board 40 are held via the fastening means 37 and housing 52. The electronics component 44 to be cooled is arranged on the further circuit board 40. A contact 42 is provided between the two circuit boards 38, 40. Again, the exemplary embodiment is symmetrical, with the carrier 36 as the axis of symmetry. Two circuit boards 38, 40 are arranged on the underside. On this further circuit board 40, there is also a further electronics component 44 to be cooled, which is cooled via a further heat-conducting element 46 through contact surfaces 47 oriented transverse to the insertion direction 35, by means of a cooler 54 (not shown). Likewise, further contact could be provided between the two circuit boards 38, each of which carries the plugs 50, 62.

In the exemplary embodiment according to FIG. 6, the heat-conducting element 46 is formed in at least two parts. It comprises at least one or more heat pipes 45 (tubular heat-conducting arrangement, filled with a heat-conducting medium particularly suitable for this purpose). The heat pipe 45 is thermally connected to the electronics component 44 whose heat is to be dissipated, for example via the thermal link 48. The heat pipe 45 is arranged in a portion adjacent to the electronics component 44 to be cooled, in particular in parallel to the insertion direction 35 in the electronics assembly 25. The heat pipe 45 is in thermal contact with a further heat-conducting element, a profile or end piece 43, which forms the contact surface 47 formed perpendicular to the insertion direction 35. This end piece 43 is, for example, a profile part made of a heat-conducting material, for example an L- or U-profile 43 made of copper or the like. A corresponding recess in the further heat-conducting element or end piece or profile 43 serves for the thermal linking of the heat pipe 45. For this purpose, the heat pipe 45 is bent by 90° and thus runs perpendicular to the insertion direction 35. The further heat-conducting element or profile 43 accommodates the portion of the heat pipe 45 bent by 90° or at least partially encloses said portion of the heat pipe 45 in order to achieve a good thermal link of the heat pipe 45 to the contact surface 47 of the further heat-conducting element or profile 43. The further heat-conducting element 43 or end piece 43 and the heat pipe 45 together form the heat-conducting element 46.

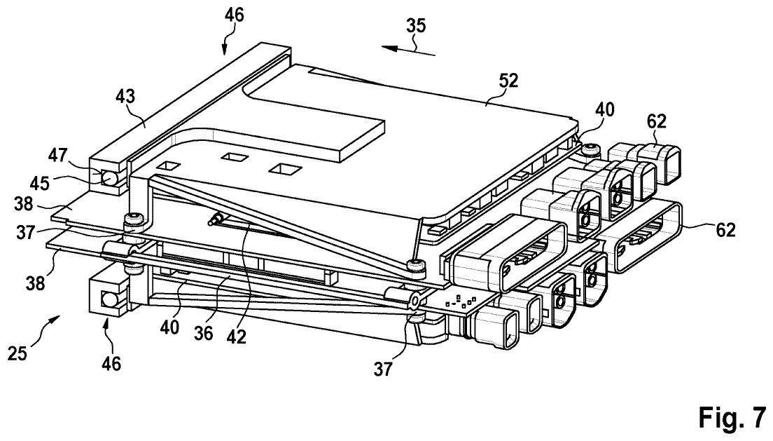

FIG. 7 is a perspective view from above of the electronics assembly 25 according to FIG. 6. It can be seen from this that the further heat-conducting element 43 or end piece with the contact surface 47 extends almost over the entire width of the circuit board 38 or the further circuit board 40 and is connected to the housing 52 at its front side. The housing 52 is curved outward in the central region oriented towards the end piece 43 to accommodate the heat pipe 45. This view also shows that the end piece 43 is designed as a U-profile that encloses the portion of the heat pipe 45 oriented transverse to the insertion direction 35 from three sides in order to ensure good heat transfer between the heat pipe 45 and the end piece 43 with the contact surface 47 oriented transverse to the insertion direction 35.

The carrier 36 projects laterally in parallel to the insertion direction 35 with respect to the side surface of the circuit board 38 projecting furthest outward or the housing 52 located thereabove. In this region, the carrier 36, in conjunction with the receptacle 18 on the housing 11, serves as an insertion mechanism for the exchangeable electronics assembly 25. The housing halves 52 protect at least the circuit boards 38, 40 from above and below, while the front sides of the electronics assembly 25 are protected from environmental influences via the front side 20 or the rear-side housing cover 22.

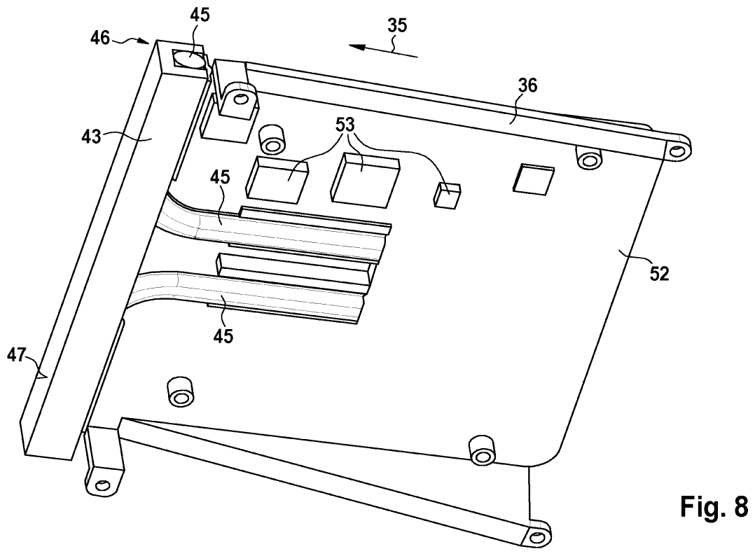

FIG. 8 is a perspective view of a housing half 52 from the inside, as used for the exemplary embodiments according to FIGS. 6 and 7. The inside of the housing 52 has a receptacle for the two heat pipes 45 in the central region on the side oriented toward the end piece 43. For this purpose, holders (not denoted in greater detail) can be provided into which the heat pipe 45 can be clamped or inserted. In addition, the inside of the housing 52 has, by way of example, at least one contact surface 53 projecting inward. Said contact surface 53 can serve to dissipate heat from further electronics components 44 that are optionally connected in a heat-conducting manner to the contact surface 53 via a further thermal link 48. The housing half 52 in turn consists of heat-conducting material and is connected to the heat-conducting element 46. In the exemplary embodiment according to FIG. 8, the cooling can take place via the portion of the heat pipe 45 inserted into the housing 52 and/or via the portion of the heat pipe 45 oriented transverse to the insertion direction 35, which heat pipe is thermally connected to the front side of the housing 52, and/or via the end piece 43, which is also thermally coupled to the front side of the housing 52.

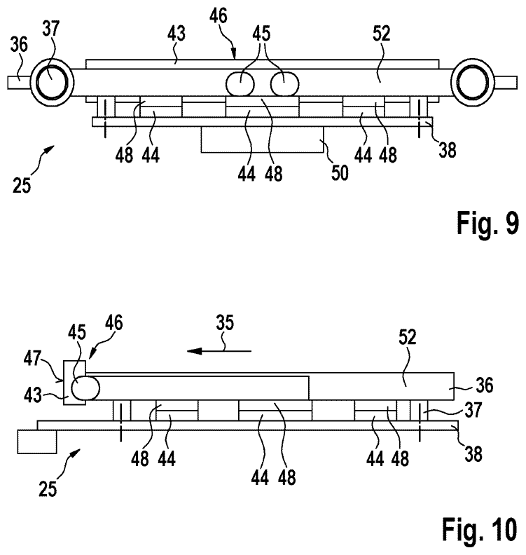

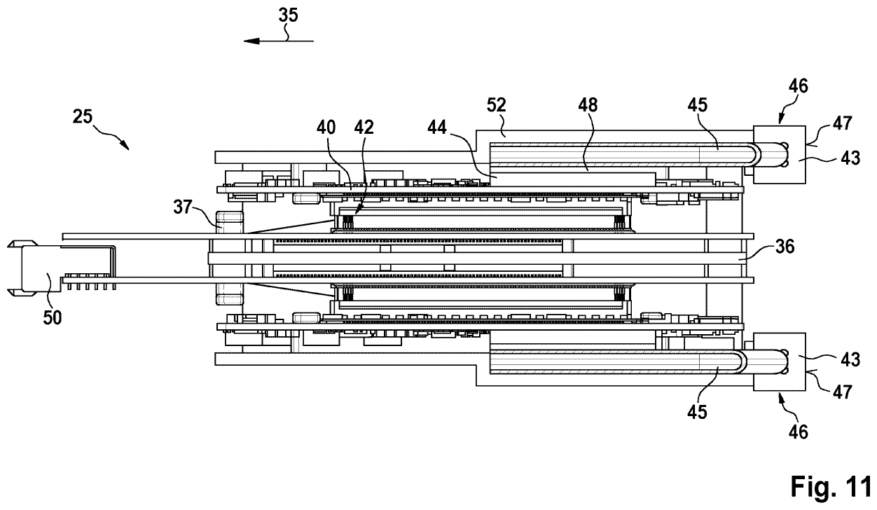

FIG. 9 is a cross section of the front view of a further exemplary embodiment, which is characterized by only a single circuit board 38. The principle of heat transfer and the insertion direction of the plug 50 parallel to the insertion direction 35 remains the same. A plurality of electronics components 44 to be cooled are arranged on the circuit board 38. For heat dissipation, one of the electronics components 44 is, for example, connected in a heat-conducting manner to at least one heat-conducting element 46, comprising a heat pipe 45 or two heat pipes 45, via the thermal link 48. The heat pipes 45 are accommodated in the housing 52 and initially run parallel (as shown in FIG. 10) to the insertion direction 35. After a 90° bend, the heat pipes 45 run transverse to the insertion direction 35 and are at least partially enclosed by the end piece 43 in a thermally conductive manner. The end piece 43 in turn has a contact surface 47, oriented transverse to the insertion direction 35, with the cooler 54 (not shown in this figure). The heat pipes 45 and end piece 43 in turn form the heat-conducting element 46.

Further electronics components 44 can be connected in a heat-conducting manner either to the heat pipe 45 or directly to the housing 52 via thermal links 48. The heat can then be dissipated to the heat-conducting element 46 via the housing 52.

The plug 50 is also arranged on the circuit board 38. Said plug is characterized by a plug-in direction parallel to the insertion direction 35. The plug 50 is located at the end of the circuit board 38 and, as shown in FIG. 10, protrudes slightly beyond the circuit board 38 to contact the rear-side circuit board 34. The plug 43 can be passed through an opening 56 in the cooler 54 so that the contact surface 47 is thermally linked to the cooler 54, for example via the thermal link or the heat-conducting medium 49.

In particular, if only one single circuit board 38 is used per electronics assembly 25, the functional division of heat conduction (which, for example, is located in the housing 52 or cover in the arrangements with a plurality of circuit boards 38, 40) and the guidance and force introduction (located in the carrier 36 in the arrangements with a plurality of circuit boards 38, 40) can be combined in one component. This one component according to FIGS. 9 and 10 is the housing 52, wherein the carrier 36 is now part of this housing 52. The housing 52 thus also has a guide for a mechanical fixing 37 and is also used to hold the heat-conducting element 46, in particular the heat pipe(s) 45 used in this exemplary embodiment. Furthermore, the housing 52 is mechanically connected to the circuit board 38.

The exemplary embodiment according to FIG. 11 is in turn characterized by cooling via the front side 20, similar to the exemplary embodiment according to FIG. 5. It differs only in that the heat-conducting element 46 consists of the heat pipe 45 and end piece 43. The end piece 43 in turn has the contact surface 47, oriented forward transverse to the insertion direction 35, with the cooler 54. The end piece 43 is connected to the front side of the cover 52, also thermally for heat dissipation of the electronics components 44 that dissipate their heat via the cover 52. The heat pipe 45 can in turn be connected to the electronics component 44 via a thermal link 48 for cooling.

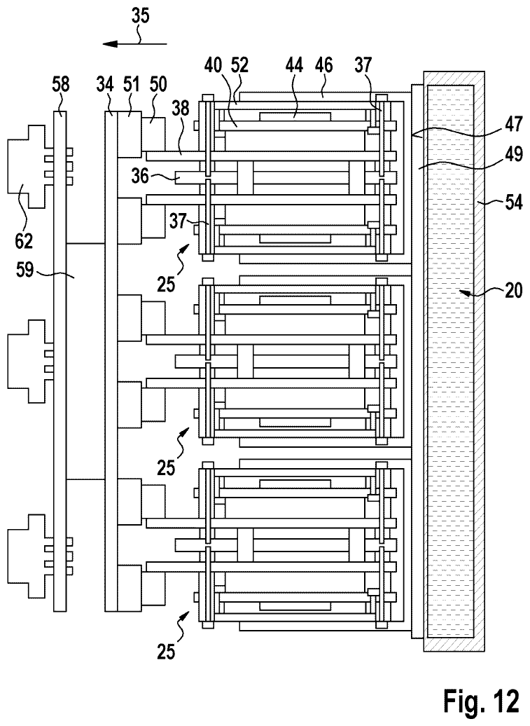

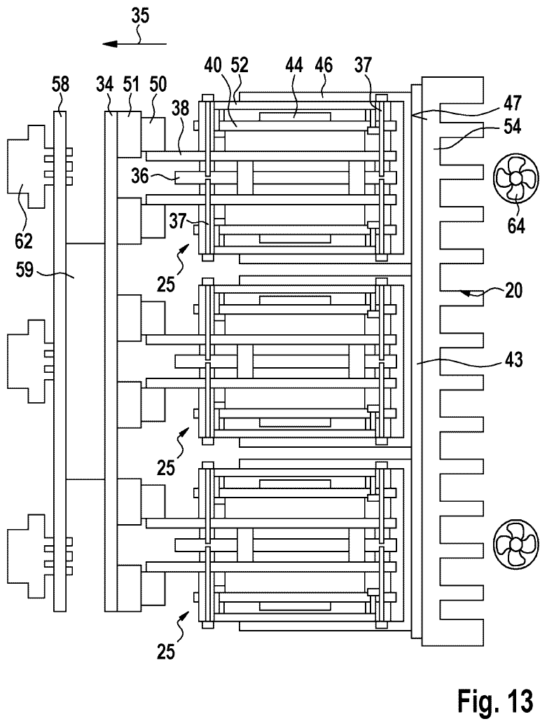

In the exemplary embodiment according to FIG. 12, the front side 20 designed as a cooler 54 could have the function of a water cooler. In the exemplary embodiment according to FIG. 13, the front side 20 designed as a cooler 54 could, for example, be provided with cooling fins in order to transfer the heat to an airflow, for example generated by fans 64.

The apparatus 10 is used in particular for exchangeable electronics components in the automotive sector. Particularly computationally intensive functions in the automotive sector, such as semi-autonomous or autonomous driving, communication modules, gateway functionalities, infotainment, security applications, etc., can be implemented in the exchangeable electronics assemblies 25 with high cooling requirements. Such functions can each be implemented in a exchangeable electronics assembly 25. The exchangeability also allows for later retrofitting of current hardware, as electronics assemblies 25 can be easily replaced.

1-15. (canceled)

16. An exchangeable electronics assembly of a motor vehicle, comprising:
at least one circuit board with at least one electronics component to be cooled arranged on the circuit board;
at least one plug oriented in parallel to an insertion direction of the electronics assembly into a housing accommodating a plurality of electronics assemblies, wherein the plug is arranged at an end of the circuit board in such a way that a rear-side circuit board oriented transverse to the insertion direction can be contacted via the plug;
at least one housing connected to the circuit board and at least partially surrounding the circuit board;
at least one insertion mechanism that cooperates with at least one receptacle of the housing accommodating a plurality of electronics assemblies; and
at least one heat-conducting element in thermal contact with the electronics component, wherein the heat-conducting element includes a contact surface oriented transverse to the insertion direction for thermally linking a cooler;
wherein the plug protrudes further than the contact surface in the insertion direction.

17. The exchangeable electronics assembly according to claim 16, wherein the contact surface is configured such that the contact surface serves to link a cooler that is arranged in front of the circuit board as seen in the insertion direction.

18. The exchangeable electronics assembly according to claim 16, wherein the plug and the contact surface are arranged on opposite sides of the circuit board.

19. The exchangeable electronics assembly according to claim 16, wherein the plug is configured to contact the rear-side circuit board by protruding through at least one opening of the cooler.

20. The exchangeable electronics assembly according to claim 16, wherein the heat-conducting element has at least one surface oriented in parallel to the insertion direction for absorbing waste heat generated by the electronics component, and at least one portion having a 90° bend for linking to the contact surface oriented transverse to the insertion direction.

21. The exchangeable electronics assembly according to claim 16, wherein at least one further circuit board is provided, and: (i) the housing is connected to both the circuit board and the further circuit board, and/or (ii) the plug is arranged on the circuit board and the electronics component to be cooled is arranged on the further circuit board and/or (iii) the circuit board and the at least one further circuit board are connected to one another via a contact.

22. The exchangeable electronics assembly according to claim 21, wherein: (i) the housing has at least one arm that protrudes over the further circuit board, and/or (ii) the housing can be connected to the circuit board, and/or (iii) the housing is configured to mechanically hold the further circuit board and/or is configured to hold the heat-conducting element and/or is configured to be attached to a carrier.

23. The exchangeable electronics assembly s according to claim 16, wherein at least one further housing is provided, which is connected to a further circuit board and a further heat-conducting element and to the carrier.

24. The exchangeable electronics assembly according to claim 16, further comprising:
at least one frame-shaped carrier for accommodating the at least one circuit board and/or for accommodating at least a part of the housing and/or for mechanical contact with receptacles that are arranged in the housing surrounding the electronics assemblies.

25. The exchangeable electronics assembly according to claim 16, wherein at least one further heat-conducting element including a flexible heat-conducting material, is provided between the heat-conducting element and: (i) the cooler and/or (ii) the electronics component.

26. The exchangeable electronics assembly according to claim 16, wherein the heat-conducting element includes: (i) at least one heat-conducting plate made of copper or aluminum, and/or (ii) at least one cavity filled with a heat-conducting medium, the cavity being in the form of a rectangle or tube or a vapor chamber or as a heat pipe.

27. The exchangeable electronics assembly according to claim 25, wherein the heat-conducting element includes at least one end piece: (i) that is in thermal contact with a tubular heat-conducting element, and/or has a profile for accommodating the further heat-conducting element.

28. The exchangeable electronics assembly according to claim 16, wherein the housing has at least one recess for the heat-conducting element and/or at least one contact surface projecting inward, for thermally cooling at least one electronics component.

29. The exchangeable electronics assembly according to claim 16, wherein a pressing device including at least one screw or lever, is provided in order to reduce a relative distance between the heat-conducting element or contact surface and the cooler, to achieve compression of the further heat-conducting element lying between the heat-conducting element or contact surface and the cooler.

30. A system, comprising:
an exchangeable electronics assembly of a motor vehicle, including:
at least one circuit board with at least one electronics component to be cooled arranged on the circuit board,
at least one plug oriented in parallel to an insertion direction of the electronics assembly into a housing accommodating a plurality of electronics assemblies, wherein the plug is arranged at an end of the circuit board in such a way that a rear-side circuit board oriented transverse to the insertion direction can be contacted via the plug,
at least one housing connected to the circuit board and at least partially surrounding the circuit board,
at least one insertion mechanism that cooperates with at least one receptacle of the housing accommodating a plurality of electronics assemblies, and
at least one heat-conducting element in thermal contact with the electronics component, wherein the heat-conducting element includes a contact surface oriented transverse to the insertion direction for thermally linking a cooler,
wherein the plug protrudes further than the contact surface in the insertion direction;
a housing to at least partially enclose the electronics assemblies which can be exchanged in the insertion direction;
at least one insertion mechanism for accommodating the exchangeable electronics assemblies;
at least one front side that is at least partially detachably connected to the housing and via which access to the exchangeable electronics assemblies arranged inside the housing is possible; and
a rear-side housing cover and the rear-side circuit board that is oriented transverse to the insertion direction of the electronics assemblies and that serves to contact the exchangeable electronics assemblies.
